(19) United States
(12) Patent Application Publication
(10) Pub. No.: US 2003/0189850 A1
(43) Pub. Date: Oct. 9, 2003

(54) Cell array system

(75) Inventors: Kohsuke Sasaki, Ube-shi (JP); Yoshiski Nishiya, Tsuruga-shi (JP)

Correspondence Address: FOLEY AND LARDNER, SUITE 500, 3000 K STREET NW, WASHINGTON, DC, 20007, US

(73) Assignee: TOYO BOSEKI KABUSHIKI KAISHA

(21) Appl. No.: 10/118,025

(22) Filed: Apr. 9, 2002

(51) Int. Cl. G11C 7/00

(52) U.S. Cl. 365/200

(57) ABSTRACT

A solid-state device for carrying out continuous detection or simultaneous detection of a subject for assay in plural cells, including a substrate and an array of spatially-separated plural sections formed on the substrate, each of the sections having an area enough to immobilize plural independent cells; a method for continuous detection or simultaneous detection of a subject for assay in plural cells using the device; and a cell assay system using the device.

### FILED OF INVENTION

The present invention relates to a device (cell array) for carrying out continuous detection or simultaneous detection of a subject for assay in plural cells and to a cell assay system (cell array system) using the device.

### BACKGROUND OF THE INVENTION

The research on cell character has increasingly become important to diagnosis or treatment for diseases, and various in situ technologies have been employed. Immunohistochemistry has routinely been carried out for making a comparison of antigen expression between normal cells and tumor cells. The amount of DNA contained in a cell has frequently been measured to determine DNA ploidy. Furthermore, FISH (fluorescence in situ hybridization; Brandriff B. F., Gordon L. A., Trask B. J., Environ. Mol. Mutagen., Vol. 18, No. 4, pp. 258-262 (1991); Gray J. W., Lucas J., Kallioniemi O., Kallioniemi A., Kuo W. L., Straume T., Tkachuk D., Tenjin T., Weier H. U., Pinkel D., Prog. Clin. Biol. Res., Vol. 372, pp. 399-411 (1991); Trask B. J., Methods Cell Biol., Vol. 35, pp. 3-35 (1991)) has widely spread even in the filed of clinical medicine for providing various pieces of information on the diagnosis of chromosomal aberration. For the quantitative evaluation of cell character, various such parameters should be analyzed.

However, the method of measurement mainly involves analyzing a subject for assay in one kind of cell by one test method. Therefore, the test of specimens one after another needs quite a long time and quite a high cost and further needs much labor.

In order to treat many cell specimens, time shortening, cost reduction, and laborsaving are required for each test per specimen. For this purpose, a novel technique different from conventional ones should be developed. It may more desirably be a micro-detection system. It may also be expected to lead to the automation of assay.

### SUMMARY OF THE INVENTION

Under these circumstances, the present inventors have extensively studied and, as a result, developed a technique in which many specimens can be placed on one slide and all the cell specimens on the slide can be treated by only one test, i.e., cell array system, thereby completing the present invention.

Thus the present invention provides:

(1) A solid-state device for carrying out continuous detection or simultaneous detection of a subject for assay in plural cells, comprising a substrate and an array of spatially-separated plural sections formed on the substrate, each of the sections having an area enough to immobilize plural independent cells.

(2) A device as set forth in (1), wherein the array of spatially-separated plural sections is formed on the substrate by printing technique using black ink.

(3) A device as set forth in (1) or (2), wherein the substrate is made of glass.

(4) A device as set forth in any of (1)-(3), wherein each of the sections has an area of 2 mm² or smaller.

(5) A device as set forth in any of (1)-(4), comprising spatially-separated sections within a rage that the distance between the central points of nearest neighbor sections is not longer than 3 mm.

(6) A method for continuous detection or simultaneous detection of a subject for assay in plural cells by chemiluminescence, bioluminescence, or fluorescence using a device as set forth in any of (1)-(5).

(7) A cell assay system for carrying out continuous detection or simultaneous detection of a subject for assay in plural cells, comprising a device as set forth in any of (1)-(5), a specimen handling system, a liquid reagent supplying system, a fluorescence observing unit, a charge-coupled device (CCD) camera, and an image processing unit.

### BRIEF DESCRIPTION OF THE DRAWINGS

FIG. 1 is a top plan view showing a pattern of sections printed on a substrate in one example of the cell array system according to the present invention.

FIG. 2A is diagram showing the results of measurement using a laser scanning cytometer (LSC) for stained DNA in the cell array system according to the present invention.

FIG. 2B is a histogram of fluorescence intensity vs. cell number for three kinds of cells enclosed in a rectangular as shown in FIG. 2A. The abscissa is fluorescence intensity and the ordinate is cell number.

FIG. 3 is a diagram showing the advantages of LSC used with the cell array system according to the present invention.

### DETAILED DESCRIPTION OF THE INVENTION

The solid-state device for carrying out continuous detection or simultaneous detection of a subject for assay in plural cells according to the present invention is characterized in that an array of spatially-separated sections is formed on a substrate, each of the sections having an area enough to immobilize plural independent cells. In the present invention, the array refers to an arrangement of plural identical units.

For the substrate of the above device, preferred are those made of a material such as silicon, quartz, glass, or ceramic. More preferred are those made of glass, and still more preferred is a slide. The substrate may be formed as a part of the finely-processed solid-state device.

Each solid-state device has an array of plural sections (i.e., regions for cell immobilization). Each section may have a shape such as a spot, a channel or groove, a dimple or hollow, a pit, a well or well-like shape, or a chamber or cell shape. The regions for various assays are formed by immobilization of cells on the respective sections of a substrate. In order to form an array of spatially-separated sections on a substrate, the application of a printing technique making use of printing ink such as black ink or color ink is most usual.

The array is not particularly limited, so long as it meets the purpose of treating many specimens. In general, the device of the present invention has an area of not larger than 5 cm², preferably about 1-5 cm². Each section usually has an area of not larger than 4 mm², preferably about 1-4 mm². It is therefore preferred that the sections are spatially separated from each other with the distance between the central points of nearest neighbor sections being in a range of not longer than 3 mm, preferably about 2-3 mm.

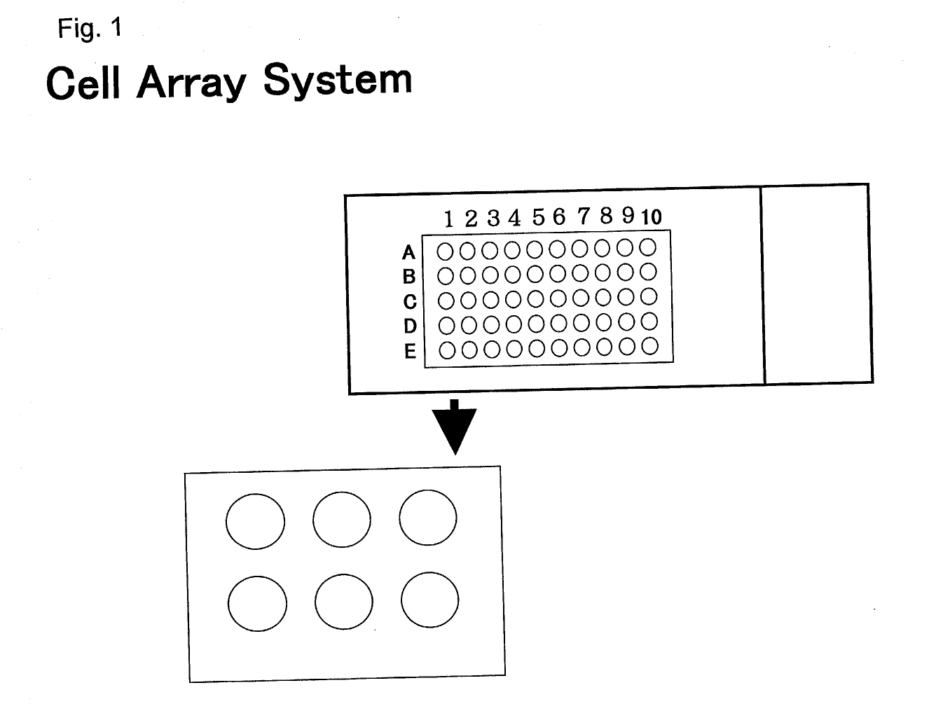

More specifically, for example, when 50 specimens of cells are continuously or simultaneously detected, the array can be obtained by printing a pattern having 5×10 circular sections, as shown in FIG. 1. In this case, each section has a diameter of 2 mm and the interval of each section is 3 mm in the distance between the central points of nearest neighbor sections. In order to prevent mixing with adjacent specimens, each circular section on the slide is surrounded by printing ink and treated so that the section itself is relatively caved from the surrounding part. In order to reduce the number of cells lost in the process of staining treatment, a silane compound, preferably triethoxyaminopropylsilane, is usually applied to the surface of each section. In order to make clear the correspondence between the respective sections and the cell species used as specimens, figures and/or alphabets are appropriately printed on the slide.

In the respective sections of the solid-state device thus formed, independent cells are immobilized, and this can be used to make it possible to assay continuously or simultaneously a subject for assay in plural cells. For the method of cell immobilization, blood cells or pleuroperitoneal effusion cells may be added dropwise as such to the sections. In the case of solid cancers, they may be attached as such to the sections; however, taking into consideration the adjustment of cell concentration, they may conveniently be added dropwise as a cell suspension. The cell suspension may be fixed with 70% ethanol, or after attachment to a slide, it may be fixed with ethanol. To each section, about 1000 cells may desirably be attached. Furthermore, expecting an error, 2-5 sections per specimen may desirably be used. The subject for assay suitable for use of the device of the present invention may include DNA ploidy, chromosomal aberration, and antibody expression.

The cell assay system of the present invention comprises a solid-state device having an array of spatially-separated sections formed on a substrate, each section having an area enough to immobilize plural independent cells, a specimen handling system, a liquid reagent supplying system, a fluorescence observing unit, a CCD camera, and an image processing unit. The assay may preferably make use of chemiluminescence, bioluminescence, or fluorescence. These are available without particular limitation, so long as they have been used in ordinary cases. In order to measure both fluorescence and chemiluminescence, the detection system may desirably have a CCD camera. Briefly, the CCD camera will capture light signals emitted from the test sections of a finely-processed device and convert them into relative light units. In the detection system based on fluorescence, direct fluorescence may be measured with an appropriate optical filter for a label fluorophore.

The whole system may be operated by a personal computer. In this case, a specially designed program will control a table moving along the XY direction, a dispenser unit, sample handling, temperature control, incubation time, and a CCD camera.

Depending upon the sensitivity on light from labeled biological molecules and unlabeled biological molecules, there may be a need to carry out the assay under the conditions in the absence of light. In order to achieve the absence of light, the case may be formed so that light does not leak in. In order to assure the satisfactory precision and accuracy of an assay, the environment which light does not leak in may preferably be controlled on temperature. The tolerance of temperature control is ±0.2° C., preferably ±0.1° C.

When a test reagent is used, the reagent comes in contact with the cells in each section, and after that, a prescribed technique of detection is carried out to detect a subject for assay whether the reagent is present or not. An important thing in this case is that the technique of detection carried out further has the ability to quantitatively determine each subject for assay. According to the present invention, a system is developed for analyzing DNA ploidy, chromosomal aberration, antibody expression, and other subjects of cells for many specimens in one test. In particular, it is of great significance in that it can be utilized for the evaluation of cancer cell biological characteristics.

### EXAMPLES

The following Examples demonstrate that multi-specimen simultaneous detection can be made possible by a system using the present device. Regarding the type of cells, the subject for assay, the test method, and other features, the present invention is not limited only to the contents of these Examples.

### Example 1

### Preparation of Cell Array

A pattern having 5×10 circular sections as shown in FIG. 1 was printed in printing ink on a slide and treated so that the sections themselves were relatively caved from the surrounding part to prepare an array. In this case, each section was 2 mm in diameter, and the interval of each section was 3 mm in the distance between the central points of nearest neighbor sections. In order to reduce the number of cells lost in the process of staining treatment, triethoxyaminopropylsilane was applied to the surface of each section. In order to make clear the correspondence between the respective sections and the cell species used as specimens, figures and alphabets were also printed on the slide. In each section of the slide thus prepared, cells were immobilized. For the method of cell immobilization, blood cells or pleuroperitoneal effusion cells may be added dropwise as such to the sections. In the case of solid cancers, they may be attached as such to the sections; however, taking into consideration the adjustment of cell concentration, they may conveniently be added dropwise as a cell suspension. The cell suspension may be fixed with 70% ethanol, or after attachment to the slide, it may be fixed with ethanol.

### EXAMPLE 2

### Analysis of DNA Ploidy

For the measurement of the amount of DNA, an LSC (laser scanning cytometer; LSC 101 available from OLYMPUS OPTICAL CO., LTD.) was used. The measurement was carried out according to the following procedures:

(1) Treating a slide having attached cells with RNase and then staining nuclear DNA with PI (propidium iodide);

(2) Measuring the amount of DNA at once all over the regions to which the cells have been attached;

(3) Subsequently, setting a gate for each case (2-5 spots); and

(4) Drawing a histogram to determine DNA ploidy.

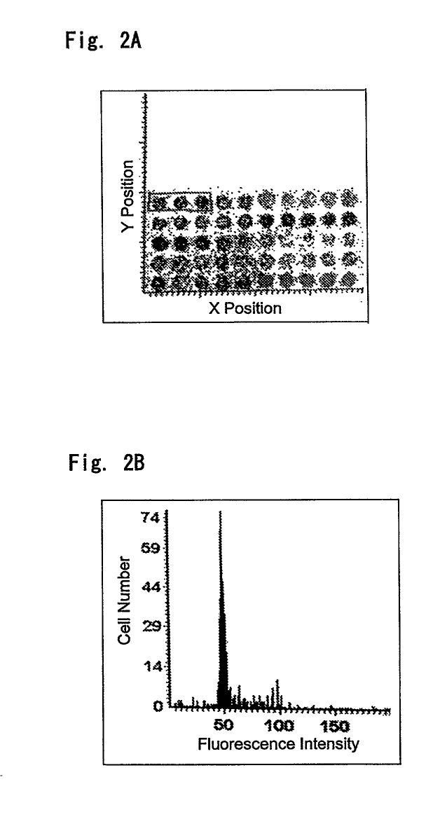

An example of the analysis using an LSC is shown in FIGS. 2A and 2B. FIG. 2A shows a diagram drawn so that the results of measurement correspond to the sections of a cell array. In FIG. 2B, the results of analysis are shown as a histogram for three kinds of cells enclosed by a rectangular as shown in FIG. 2A.

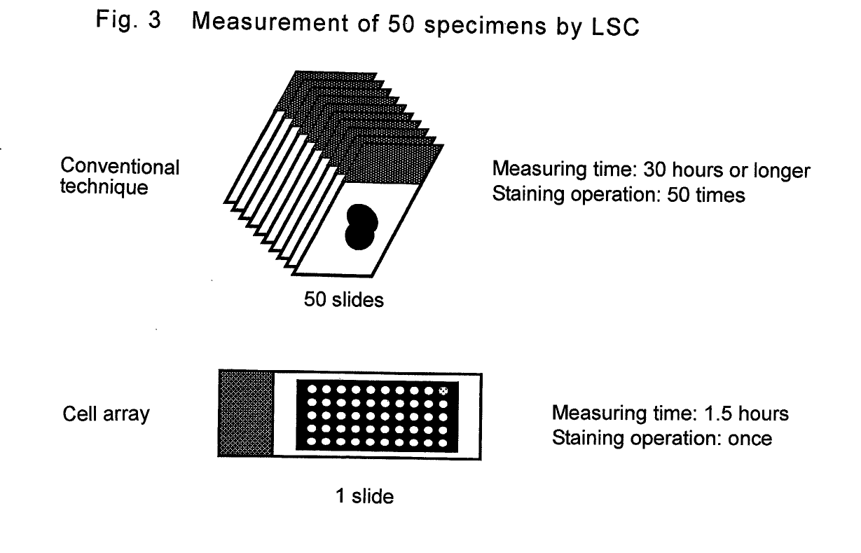

FIG. 3 illustrates the effects of the cell array system according to the present invention. When fifty specimens are measured by an LSC, the conventional method involves 50 staining operations and a measuring time of 30 hours or longer, while the introduction of a cell array system needs only one staining operation and shortens the measuring time to 1.5 hours.

For another test method, the analysis of chromosomal aberration by FISH is carried out by observing about 200 cells for each spot and determining the ratio of abnormal cells. When the analysis for the amount of DNA and the analysis by FISH are effected on the same slide, DNA ploidy is first determined, and after washing PI away, ordinary FISH is carried out. The analysis of antigen expression was carried out after the staining of antigens by immunohistochemistry. A combination of fluorescent antibody technique (antigens are stained with FITC (fluorescein isothiocyanate)) and PI staining makes possible automatic analysis concerning the count of cells positive for antigen expression.

As described above, the device of the present invention can be used for the continuous or simultaneous treatment of many cell specimens, making it possible to realize time shortening, cost reduction, and laborsaving for the test per specimen.

1. A solid-state device for carrying out continuous detection or simultaneous detection of a subject for assay in plural cells, comprising a substrate and an array of spatially-separated plural sections formed on the substrate, each of the sections having an area enough to immobilize plural independent cells.

2. A device according to claim 1, wherein the array of spatially-separated plural sections is formed on the substrate by printing technique using black ink.

3. A device according to claim 1, wherein the substrate is made of glass.

4. A device according to claim 1, wherein each of the sections has an area of 2 mm² or smaller.

5. A device according to claim 1, comprising spatially-separated sections within a rage that the distance between the central points of nearest neighbor sections is not longer than 3 mm.

6. A method for continuous detection or simultaneous detection of a subject for assay in plural cells by chemiluminescence, bioluminescence, or fluorescence using a device according to claim 1.

7. A cell assay system for carrying out continuous detection or simultaneous detection of a subject for assay in plural cells, comprising a device according to claim 1, a specimen handling system, a liquid reagent supplying system, a fluorescence observing unit, a charge-coupled device camera, and an image processing unit.
